(19) United States
(12) Patent Application Publication
(10) Pub. No.: US 2026/0245603 A1
(43) Pub. Date: Aug. 20, 2026

(54) MULTI-DIE MEMORY BIT LINES

(71) Applicant: Apple Inc., Cupertino, CA (US)

(72) Inventor: Michael A. DREESEN, Austin, TX (US)

(21) Appl. No.: 19/058,405

(22) Filed: Feb. 20, 2025

(51) Int. Cl. G11C 7/10; G11C 7/06; G11C 7/12

(52) U.S. Cl. CPC G11C 7/1069; G11C 7/06; G11C 7/12

(57) ABSTRACT

A computer system that employs bit lines shared between at least two integrated circuits is disclosed. A particular integrated circuit may transmit a memory access command to a different integrated circuit that includes an array of memory cells. The different integrated circuit may select a portion of the array of memory cells upon receiving the memory access command. The selected portion of the array of memory cells may generate respective signals on the shared bit lines, which are then received by the particular integrated circuit.

### FIELD

This disclosure relates to the field of integrated circuit implementation and, more particularly, to the implementation of memory circuits.

### BACKGROUND

Computer systems typically include a number of interconnected integrated circuits. Such circuits can include processor or processor core circuits, analog/mixed-signal circuits, power management circuits, memory circuits, and the like. In some computer systems, multiple different circuits, e.g., processor circuits and memory circuits, may be integrated onto a common substrate creating a system-on-a-chip or SoC.

The integrated circuits in a computer system may communicate using communication channels or links to transmit and receive data symbols or bits. The communication channels may support parallel communication in which multiple data bits are transmitted in parallel, or serial communication in which data bits are transmitted one bit at a time in a serial fashion.

In some cases, multiple integrated circuits may be coupled to a common communication channel (also referred to as a “switch fabric”) that allows an integrated circuit to send requests to other integrated circuits over the switch fabric. In other cases, one integrated circuit may be coupled to another integrated circuit over a dedicated communication channel. For example, an SoC may be coupled to a memory circuit over a dedicated communication channel.

### BRIEF DESCRIPTION OF THE DRAWINGS

FIG. 1 is a block diagram depicting an embodiment of a computer system.

FIG. 2 is a block diagram depicting an embodiment of a primary memory control circuit.

FIG. 3 is a block diagram depicting an embodiment of a secondary memory control circuit.

FIG. 4 is a block diagram depicting an embodiment of a memory array circuit.

FIG. 5 is a block diagram depicting an embodiment of a column circuit for a memory array circuit.

FIG. 6 is a block diagram depicting an embodiment of a computer system that includes multiple integrated circuits.

FIG. 7 is a flow diagram depicting an embodiment of a method for accessing a memory device in a computer system.

FIG. 8 is a block diagram of an embodiment of a device that may include a primary memory control circuit.

FIG. 9 is a block diagram of various embodiments of computer systems that may include logic gates.

FIG. 10 illustrates an example of a non-transitory computer-readable storage medium that stores circuit design information.

### DETAILED DESCRIPTION

Computer systems can include multiple memory circuits that are used to store data and program instructions. Some memory circuits may be used as main memory, while other memory circuits may function as cache memory circuits configured to store frequently used data and program instructions.

In some cases, a memory circuit can be accessed by multiple circuit blocks located on different integrated circuits. For example, a higher-level cache memory circuit may be shared between multiple processor circuits located on corresponding integrated circuits.

To allow different circuit blocks to access a common memory circuit, memory access commands from the different circuit blocks are transmitted to the common memory circuit via a communication bus. For example, a particular circuit block may transmit a memory read command to the memory circuit. Once the command has been received by the memory circuit, the requested data can be retrieved from the storage cells in the memory circuit. The data can then be relayed back to the particular circuit block using the communication bus.

Relaying data from the memory circuit back to a requesting circuit block can add delay to the delivery of the data, effectively increasing the access time to the memory. Moreover, as the data is relayed over the communication bus, the wires of the bus have to be charged or discharged according to individual bits in the data. Such charging and discharging contribute to the overall power consumption associated with a memory access.

The embodiments illustrated in the drawings and described below provide techniques for sharing bit lines of a memory array circuit across multiple integrated circuits. By sharing bit lines of the memory array circuit, access to the memory array circuit can be made without having to use a communication bus common to the multiple integrated circuits, thereby reducing access time to the memory array circuit. Moreover, reducing the use of the communication bus can also reduce power consumption.

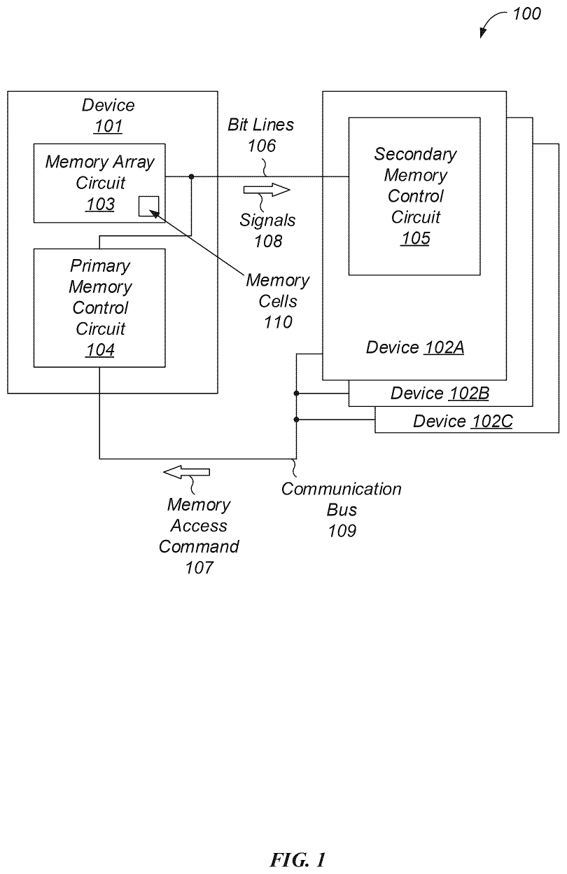

A block diagram of a computer system is depicted in FIG. 1. As illustrated, computer system 100 includes device 101 and devices 102A-102C. Although only four devices are depicted in the embodiment of FIG. 1, in other embodiments, any suitable number of devices can be employed.

Device 101 and devices 102A-102C may, in some embodiments, be implemented as standalone integrated circuits. In other embodiments, any of device 101 and devices 102A-102C may be implemented as systems-on-a-chip (or “SoCs”) that include multiple circuit blocks configured to perform respective functions.

Device 102A includes secondary memory control circuit 105 which is configured to generate memory access command 107. In various embodiments, device 102A is configured to transmit memory access command 107 to device 101 via communication bus 109. It is noted that communication bus 109 may employ any suitable communication protocol that allows multiple devices to send messages to and receive messages from one another.

Devices 102B and 102C are also coupled to communication bus 109, and may be configured to send respective memory access commands. Although only four devices are shown being coupled to communication bus 109, in other embodiments, any suitable number of devices or integrated circuits may be coupled to communication bus 109.

Device 101 includes memory array circuit 103 and primary memory control circuit 104. Although device 101 is depicted as including two circuit blocks, in other embodiments, device 101 can include any suitable number of additional circuit blocks.

Memory array circuit 103 includes memory cells 110 (also referred to as “storage cells”). As described below, memory cells 110 may be arranged in an array of rows and columns and configured to store corresponding bits.

Primary memory control circuit 104 is configured, in response to receiving memory access command 107, to select a subset of memory cells 110. In various embodiments, the subset of memory cells 110 may be configured to generate respective ones of signals 108 on bit lines 106. In various embodiments, signals 108 may be single-ended signals or differential signals.

Secondary memory control circuit 105 is configured to receive signals 108 via bit lines 106. As described below, secondary memory control circuit 105 may be further configured to amplify signals 108 to determine data stored in the subset of memory cells 110. It is noted that bit lines 106 may be coupled to other devices. For example, bit lines 106 may be coupled to devices 102B and 102C. In some embodiments, subsets of bit lines 106 may be coupled to corresponding devices.

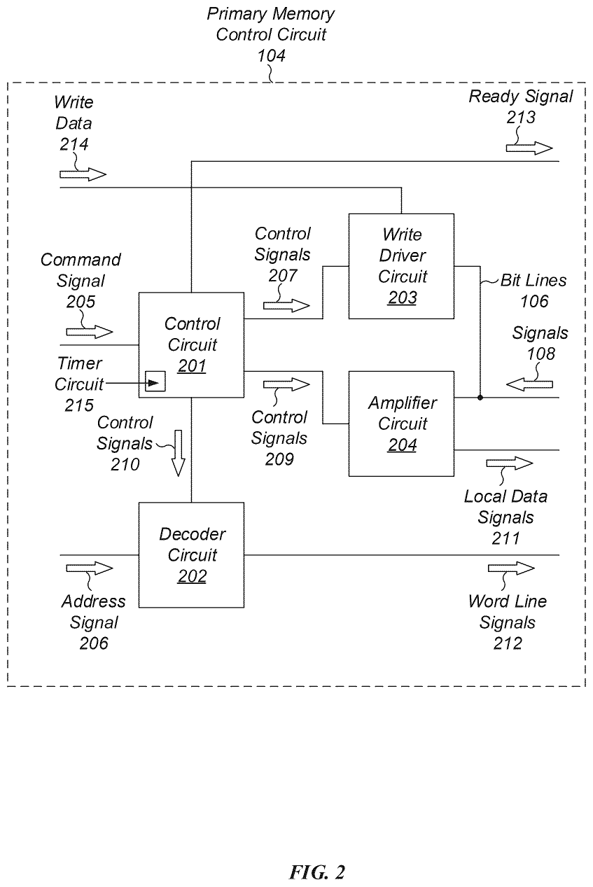

Turning to FIG. 2, a block diagram of an embodiment of primary memory control circuit 104 is depicted. As illustrated, primary memory control circuit 104 includes control circuit 201, decoder circuit 202, write driver circuit 203, and amplifier circuit 204.

Control circuit 201 is configured to generate control signals 207 and control signals 209 using command signal 205. In various embodiments, command signal 205 may be included in memory access command 107. To generate control signals 207, control circuit 201 may be further configured to activate control signals 207 in response to command signal 205 including a write command. Alternatively, in response to command signal 205 including a read command, control circuit 201 is also configured to activate control signals 209.

In other embodiments, control circuit 201 includes timer circuit 215. In such cases, timer circuit 215 may be configured to track a particular period of time from when command signal 205 is received. After the particular period of time has elapsed, control circuit 201 may activate ready signal 213. In various embodiments, the particular period of time may correspond to an amount of time for sufficient amplitude to develop in signals 108 after memory access command 107 has been received.

In response to command signal 205 including either a read or write command, control circuit 201 is configured to activate control signals 210 to enable decoder circuit 202. Additionally, control circuit 201 is configured, in response to command signal 205 including a read command, to activate ready signal 213. Control circuit 201 may be further configured to wait a particular period of time from receiving command signal 205 to activate ready signal 213. In various embodiments, the particular period of time may correspond to a time for a subset of memory cells 110 to generate sufficient signal on bit lines 106 in response to an activation of a given one of word line signals 212.

As used herein, activation of a signal refers to transitioning a signal to a voltage level sufficient to activate an n-channel metal-oxide semiconductor field-effect transistor (MOSFET), fin field-effect transistor (FinFET), gate-all-around field-effect transistor (GAAFET), or any other suitable transconductance device. In some cases, a signal may be referred to as “active low” in which case activating such a signal refers to transitioning the signal to a voltage level sufficient to deactivate an n-channel MOSFET, FinFET, GAAFET, or other suitable transconductance device while activating a p-channel MOSFET, FinFET, GAAFET, or other suitable transcondutance device.

Decoder circuit 202 is configured to generate word line signals 212 using control signals 210 and address signal 206. In various embodiments, address signal 206 may be included in memory access command 107. To generate word line signals 212, decoder circuit 202 is configured, in response to an activation of control signals 210, to perform a decode operation on address signal 206 to activate a given one of word line signals 212 that correspond to a value of address signal 206.

Write driver circuit 203 is configured to drive write data 214 onto bit lines 106 in response to an activation of control signals 207. In various embodiments, write data 214 may be included in memory access command 107 when command signal 205 corresponds to a write command. In various embodiments, write driver circuit 203 may be configured to drive either singled-ended data or differential data onto bit lines 106.

Amplifier circuit 204 is configured, in response to an activation of control signals 209, to amplify signals 108 to generate local data signals 211. In various embodiments, local data signals 211 are sent to a given circuit block included in device 101 that generated a memory access command. In cases where command signal 205 and address signal 206 originate from one of devices 102A-102C, amplifier circuit 204 may be configured to remain inactive. In some embodiments, amplifier circuit 204 may be configured to pre-charge bit lines 106 in response to a determination that secondary memory control circuit 105 has sensed the data stored in memory cells 110. In various embodiments, amplifier circuit 204 may be configured to pre-charge bit lines 106 to a voltage level of a power supply node or any other suitable voltage.

In various embodiments, amplifier circuit 204 may be implemented using one or more differential amplifier circuits, single-ended amplifier circuits, or any suitable analog amplifier circuits. In other embodiments, amplifier circuit 204 may be implemented using latched-based amplifier circuits.

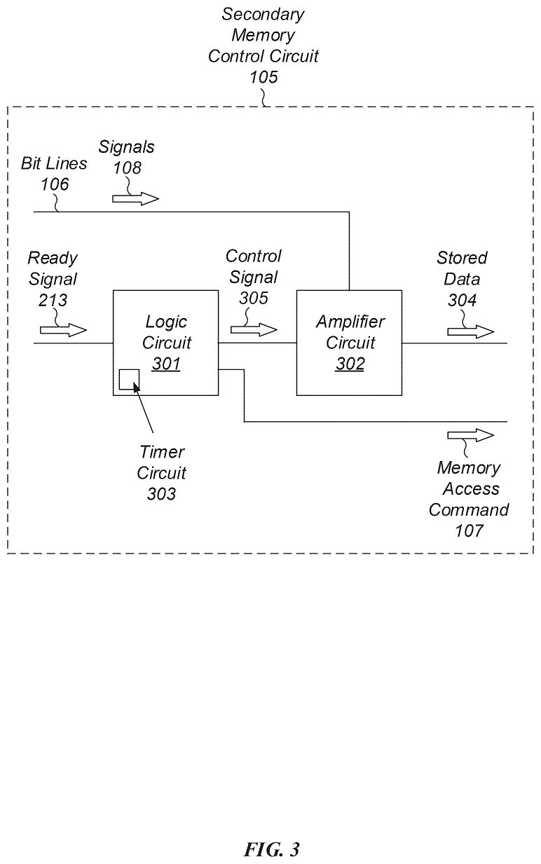

Turning to FIG. 3, a block diagram of an embodiment of secondary memory control circuit 105 is depicted. As illustrated, secondary memory control circuit 105 includes logic circuit 301 and amplifier circuit 302.

Logic circuit 301 is configured to generate memory access command 107. In various embodiments, logic circuit 301 may be configured to generate memory access command 107 in response to receiving a request from a given circuit block included in device 102A. As described above, memory access command 107 may be a read access command or a write access command. In cases of a write access command, memory access command 107 may include data to be stored in addition to an address and a command for primary memory control circuit 104.

Additionally, logic circuit 301 may be further configured to generate control signal 305 to activate amplifier circuit 302. In some embodiments, logic circuit 301 may be configured to generate control signal 305 using ready signal 213 which is received from primary memory control circuit 104. In certain embodiments, ready signal 213 may be activated in response to a determination that there is sufficient amplitude in signals 108 to allow for proper amplification.

In other embodiments, logic circuit 301 includes timer circuit 303. In such cases, timer circuit 303 may be configured to track a particular period of time from when memory access command 107 is generated. After the particular period of time has elapsed, logic circuit 301 may activate control signal 305. In various embodiments, the particular period of time may correspond to an amount of time for sufficient amplitude to develop in signals 108 after primary memory control circuit 104 has received memory access command 107.

Logic circuit 301 may be implemented using any suitable combination of sequential and combinatorial logic circuits. In some embodiments, logic circuit 301 may be implemented using a microcontroller or other suitable state machine.

Amplifier circuit 302 is coupled to bit lines 106 and is configured to amplify signals 108 to generate stored data 304. In various embodiments, amplifier circuit 302 may be further configured to amplify signals 108 in response to a determination that control signal 305 has been activated.

In various embodiments, amplifier circuit 302 may be implemented using one or more differential amplifier circuits, single-ended amplifier circuits, or any suitable analog amplifier circuits. In other embodiments, amplifier circuit 302 may be implemented using latched-based amplifier circuits.

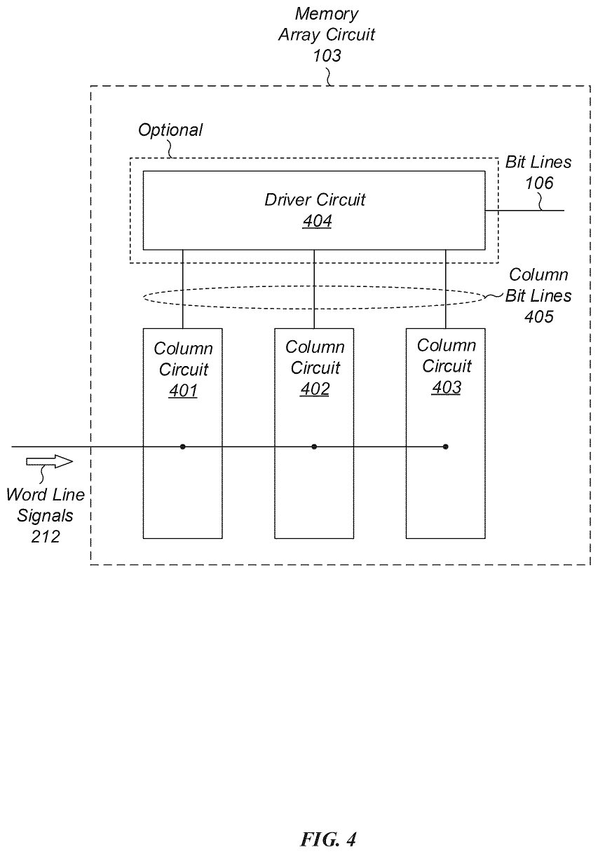

Turning to FIG. 4, a block diagram of an embodiment of memory array circuit 103 is depicted. As illustrated, memory array circuit 103 includes column circuit 401-403 and optional driver circuit 404.

Colum circuits 401-403 are coupled to word line signals 212. As described below, column circuits 401-403 include respective groups of memory cells (also referred to as “storage cells”). In various embodiments, column circuits 401-403 are configured, in response to an activation of a given one of word line signals 212, to activate respective subsets of their respective groups of memory cells. Once activated, the respective groups of memory cells are configured to generate corresponding signals on column bit lines 405.

Although only three column circuits are depicted in the embodiment of FIG. 4, in other embodiments, any suitable number of column circuits may be employed. In some cases, multiple column circuits may be grouped into banks or partitions which can be activated individually or in parallel.

Driver circuit 404 is coupled between column bit lines 405 and bit lines 106. In various embodiments, driver circuit 404 may include a decoder circuit configured to couple at least one of column bit lines 405 to bit lines 106. In other embodiments, driver circuit 404 may include one or more amplifier circuits configured to amplify signals on column bit lines 405 before relaying the signals to bit lines 106. It is noted that driver circuit 404 is optional. In various embodiments, column bit lines 405 may be coupled to bit lines 106 without any intervening circuitry.

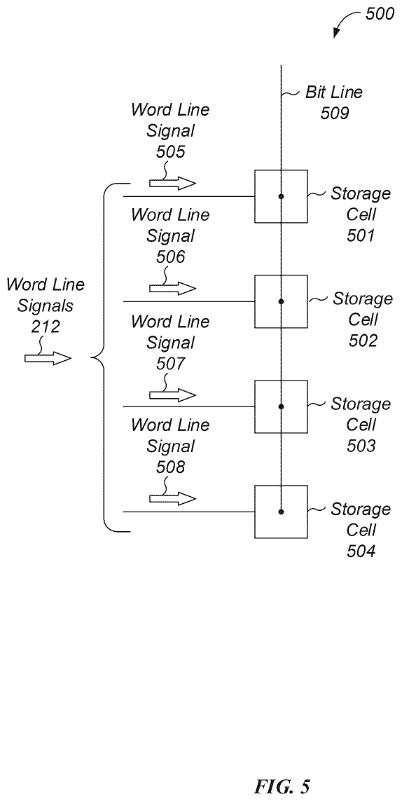

Turning to FIG. 5, a block diagram of an embodiments of a column circuit is depicted. As illustrated, column circuit 500 includes storage cells 501-504. In various embodiments, column circuit 500 may correspond to any of column circuits 401-403 as depicted in the embodiment of FIG. 4.

Storage cells 501-504 are coupled to bit line 509. In various embodiments, bit line 509 may correspond to any of column bit lines 405, or to any of bit lines 106 in cases where driver circuit 404 is omitted. Storage cells 501-504 may be implemented using dynamic memory cells, static memory cells, non-volatile memory cells, or any suitable type of memory cells.

Although bit line 509 is depicted as a single wire, in other embodiments, bit line 509 may include multiple wires. For example, in some cases, a pair of bit lines may be employed. In such cases, storage cells 501-504 may, when activated, generate a differential signal on the pair of bit lines such that a difference between the voltage levels of the two bit lines corresponds to data stored in storage cells 501-504.

In various embodiments, storage cell 501 is activated by an activation of word line signal 505, and storage cell 502 is activated by an activation of word line signal 506. In a similar fashion, storage cell 503 is activated by an activation of word line signal 507, and storage cells 504 is activated by an activation of word line signal 508. In some cases, word line signals 505-508 may be included in word line signals 212. It is noted that a number of word line signals may correspond to a number of storage cells coupled to a common bit line.

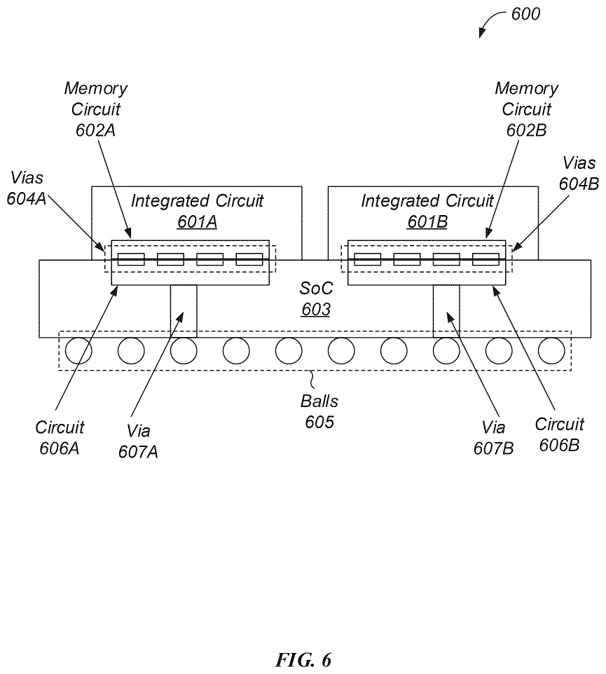

Turning to FIG. 6, a block diagram of an embodiment of a computer system that includes multiple integrated circuits is depicted. As illustrated, computer system 600 includes integrated circuit 601A and integrated circuit 601B, each of which is coupled to a system-on-a-chip, i.e., SoC 603. In various embodiments, computer system 600 may correspond to computer system 100 as depicted in FIG. 1. Although two integrated circuits are depicted as being coupled to SoC 603, in other embodiments, any suitable number of integrated circuits may be coupled to SoC 603.

Integrated circuit 601A includes memory circuit 602A, while integrated circuit 601B includes memory circuit 602B. In various embodiments, either of integrated circuit 601A or integrated circuit 601B may correspond to device 101 as depicted in FIG. 1. Memory circuit 602A may, in some embodiments, include instances of memory array circuit 103 and primary memory control circuit 104, while memory circuit 602B may also include instances of memory array circuit 103 and primary memory control circuit 104. Although integrated circuit 601A is depicted as only including memory circuit 602A, and integrated circuit 601B is depicted as only including memory circuit 602B, in other embodiments, integrated circuit 601A and integrated circuit 601B may include any suitable number of additional circuit blocks.

Memory circuit 602A is coupled to SoC 603 using vias 604A. In various embodiments, vias 604A are coupled to corresponding bit lines, e.g., bit line 106, and span a distance from bit lines 106 to a connection point on SoC 603. In a similar fashion, memory circuit 602B is coupled to SoC 603 using vias 604B which couple corresponding bit lines to corresponding connection points on SoC 603. In various embodiments, vias 604A and vias 604B may be implemented as hybrid bond vias, or any other suitable via structure configured to couple circuit nodes from one integrated circuit to another. Although vias 604A and vias 604B are depicted as including four vias each, in other embodiments, any suitable number of vias may be employed.

SoC 603 includes circuits 606A and 606B. In various embodiments, circuits 606A and 606B may include instances of secondary memory control circuit 105. While SoC 603 is depicted as only including two circuit blocks, in other embodiments, SoC 603 may include any suitable number of circuit blocks. In some embodiments, one or more circuit nodes of circuit 606A and circuit 606B are coupled to balls 605 using through-silicon vias. For example, a particular circuit node of circuit 606A is coupled to a particular ball of balls 605 using via 607A. In a similar fashion, a different circuit node of circuit 606B is coupled to a different ball of balls 605 using via 607B.

In some embodiments, balls 605 (also referred to as “bumps”) may be implemented using solder or any other suitable material that can be used to make electrical contact between SoC 603 and a printed circuit board, substrate, or the like. Although only 10 balls are depicted in the embodiment of FIG. 6, in other embodiments, any suitable number of balls may be employed.

To summarize, various embodiments of a computer system are disclosed. Broadly speaking, the computer system may include a first integrated circuit and a second integrated circuit. The first integrated circuit may include a first memory control circuit configured to generate a memory access command. The second integrated circuit may be coupled to the first integrated circuit via a plurality of bit lines, and may include a second memory control circuit and a memory array that includes a plurality of memory cells. The second memory control circuit may be configured, in response to receiving the memory access command, to select a subset of the plurality of memory cells that may be configured to generate respective signals on the plurality of bit lines. The first memory control circuit may be further configured to receive the plurality of signals via the plurality of bit lines.

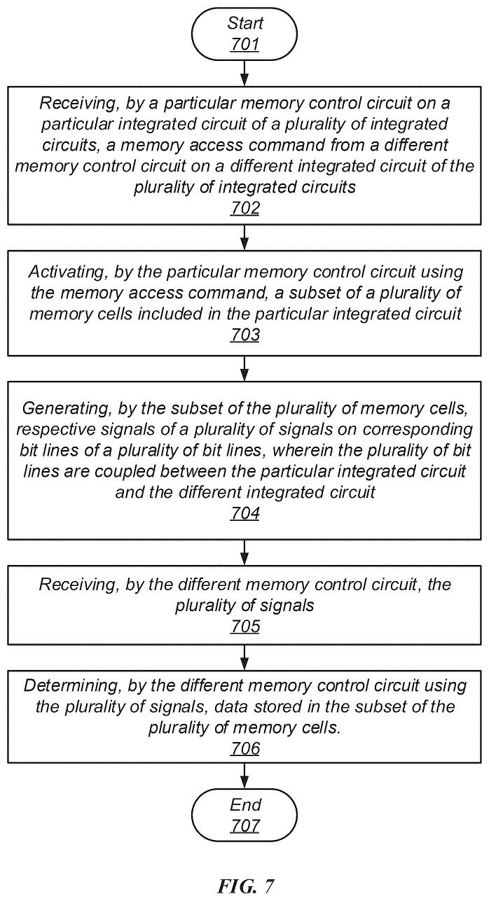

Turning to FIG. 7, a flow diagram depicting an embodiment of a method for accessing a memory circuit in a computer system is illustrated. The method, which may be applied to various computer systems, e.g., computer system 100 as depicted in FIG. 1, begins in block 701.

The method includes receiving, by a particular memory control circuit on a particular integrated circuit of a plurality of integrated circuits, a memory access command from a different memory control circuit on a different integrated circuit of the plurality of integrated circuits (block 702).

The method also includes activating, by the particular memory control circuit using the memory access command, a subset of a plurality of memory cells included in the particular integrated circuit (block 703). In various embodiments, the plurality of memory cells is arranged in an array including a plurality of rows and a plurality of columns. The subset of the plurality of memory cells may be coupled to a particular word line of a plurality of word lines, and the subset of the plurality of memory cells are coupled to corresponding column bit lines of a plurality of column bit lines. In some embodiments, activating, by the particular memory control circuit, the subset of the plurality of memory cells includes coupling, by the particular memory control circuit, the corresponding column bit lines of the plurality of column bit lines to corresponding bit lines of a plurality of bit lines.

In some embodiments, the method may additionally include performing, by the particular memory control circuit, a decode operation using an address included in the memory access command. In such cases, the method may also include activating, by the particular memory control circuit, the particular word line using a result of the decode operation.

The method further includes generating, by the subset of the plurality of memory cells, respective signals of a plurality of signals on corresponding bit lines of the plurality of bit lines (block 704). In various embodiments, the plurality of bit lines are coupled between the particular integrated circuit and the different integrated circuit.

The method also includes receiving, by the different memory control circuit, the plurality of signals (block 705). In some embodiments, the method may additionally include transmitting, by the particular memory control circuit, a ready signal in response to determining a particular time period has elapsed since receiving the memory access command, and receiving the ready signal by the different memory control circuit.

The method further includes determining, by the different memory control circuit using the plurality of signals, data stored in the subset of the plurality of memory cells (block 706). In various embodiments, determining the data stored in the subset of the plurality of memory cells includes amplifying, by the different memory control circuit, the plurality of signals. In some embodiments, the method may additionally include amplifying, by the different memory control circuit, the plurality of signals in response to determining a particular time period has elapsed since sending the memory access command to the particular memory control circuit. In cases where a ready signal is employed, the method may also include amplifying, by the different memory control circuit, the plurality of signals in response to receiving the ready signal.

In other embodiments, the method may include pre-charging, by the particular memory control circuit, the plurality of bit lines in response to determining the different memory control circuit has sensed, using the plurality of signals, the data stored in the subset of the plurality of memory cells. The method concludes in block 707.

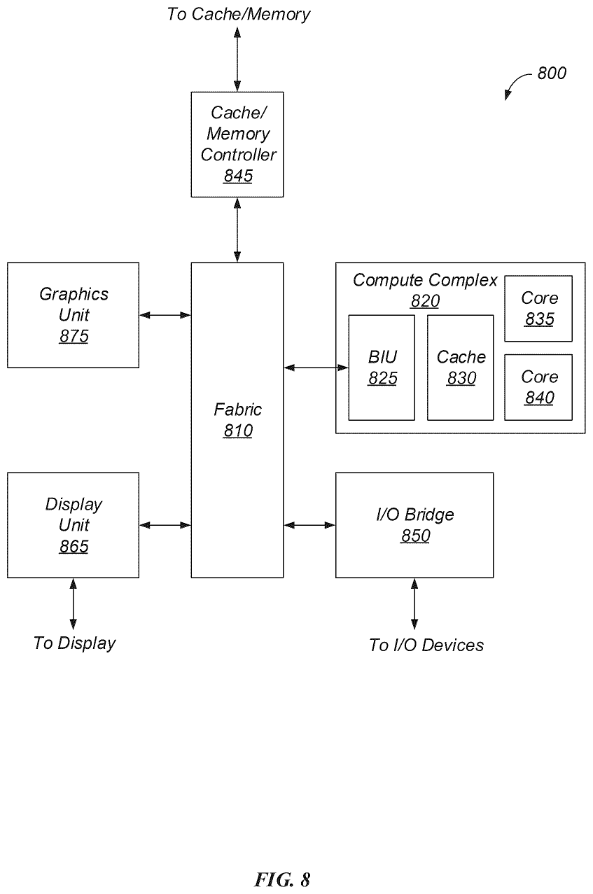

Referring now to FIG. 8, a block diagram illustrating an example embodiment of a device is shown. In some embodiments, elements of device 800 may be included within a system-on-a-chip. In some embodiments, device 800 may be included in a mobile device, which may be battery-powered. Therefore, power consumption by device 800 may be an important design consideration. In the illustrated embodiment, device 800 includes fabric 810, compute complex 820, input/output (I/O) bridge 850, cache/memory controller 845, graphics unit 875, and display unit 865. In some embodiments, device 800 may include other components (not shown) in addition to, or in place of, the illustrated components, such as video processor encoders and decoders, image processing or recognition elements, computer vision elements, etc.

Fabric 810 may include various interconnects, buses, MUX's, controllers, etc., and may be configured to facilitate communication between various elements of device 800. In some embodiments, portions of fabric 810 may be configured to implement various different communication protocols. In other embodiments, fabric 810 may implement a single communication protocol, and elements coupled to fabric 810 may convert from the single communication protocol to other communication protocols internally.

In the illustrated embodiment, compute complex 820 includes bus interface unit (BIU) 825, cache 830, and cores 835 and 840. In various embodiments, compute complex 820 may include various numbers of processors, processor cores, and caches. For example, compute complex 820 may include 1, 2, or 4 processor cores, or any other suitable number. In one embodiment, cache 830 is a set associative L2 cache. In some embodiments, cores 835 and 840 may include internal instruction and data caches. In some embodiments, a coherency unit (not shown) in fabric 810, cache 830, or elsewhere in device 800, may be configured to maintain coherency between various caches of device 800. BIU 825 may be configured to manage communication between compute complex 820 and other elements of device 800. Processor cores, such as cores 835 and 840, may be configured to execute instructions of a particular instruction set architecture (ISA) which may include operating system instructions and user application instructions. These instructions may be stored in a computer readable medium such as a memory coupled to cache/memory controller 845 as discussed below.

As used herein, the term “coupled to” may indicate one or more connections between elements, and a coupling may include intervening elements. For example, in FIG. 8, graphics unit 875 may be described as “coupled to” a memory through fabric 810 and cache/memory controller 845. In contrast, in the illustrated embodiment of FIG. 8, graphics unit 875 is “directly coupled” to fabric 810 because there are no intervening elements.

Cache/memory controller 845 may be configured to manage transfer of data between fabric 810 and one or more caches and memories. For example, cache/memory controller 845 may be coupled to an L3 cache, which may, in turn, be coupled to a system memory. In other embodiments, cache/memory controller 845 may be directly coupled to a memory. In some embodiments, cache/memory controller 845 may include one or more internal caches. Memory coupled to cache/memory controller 845 may be any type of volatile memory, such as dynamic random access memory (DRAM), synchronous DRAM (SDRAM), double data rate (DDR, DDR2, DDR3, etc.) SDRAM (including mobile versions of SDRAMs such as mDDR3, etc., and/or low power versions of SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to cache/memory controller 845 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 820 to cause the computing device to perform functionality described herein.

Graphics unit 875 may include one or more processors, e.g., one or more graphics processing units (GPUs). Graphics unit 875 may receive graphics-oriented instructions, such as OPENGL®, Metal®, or DIRECT3D® instructions, for example. Graphics unit 875 may execute specialized GPU instructions or perform other operations based on the received graphics-oriented instructions. Graphics unit 875 may generally be configured to process large blocks of data in parallel, and may build images in a frame buffer for output to a display, which may be included in the device or may be a separate device. Graphics unit 875 may include transform, lighting, triangle, and rendering engines in one or more graphics processing pipelines. Graphics unit 875 may output pixel information for display images. Graphics unit 875, in various embodiments, may include programmable shader circuitry which may include highly parallel execution cores configured to execute graphics programs, which may include pixel tasks, vertex tasks, and compute tasks (which may or may not be graphics-related).

Display unit 865 may be configured to read data from a frame buffer and provide a stream of pixel values for display. Display unit 865 may be configured as a display pipeline in some embodiments. Additionally, display unit 865 may be configured to blend multiple frames to produce an output frame. Further, display unit 865 may include one or more interfaces (e.g., MIPI® or embedded display port (eDP)) for coupling to a user display (e.g., a touchscreen or an external display).

I/O bridge 850 may include various elements configured to implement universal serial bus (USB) communications, security, audio, and low-power always-on functionality, for example. I/O bridge 850 may also include interfaces such as pulse-width modulation (PWM), general-purpose input/output (GPIO), serial peripheral interface (SPI), and inter-integrated circuit (I2C), for example. Various types of peripherals and devices may be coupled to device 800 via I/O bridge 850.

In some embodiments, device 800 includes network interface circuitry (not explicitly shown), which may be connected to fabric 810 or I/O bridge 850. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 800 with connectivity to various types of other devices and networks.

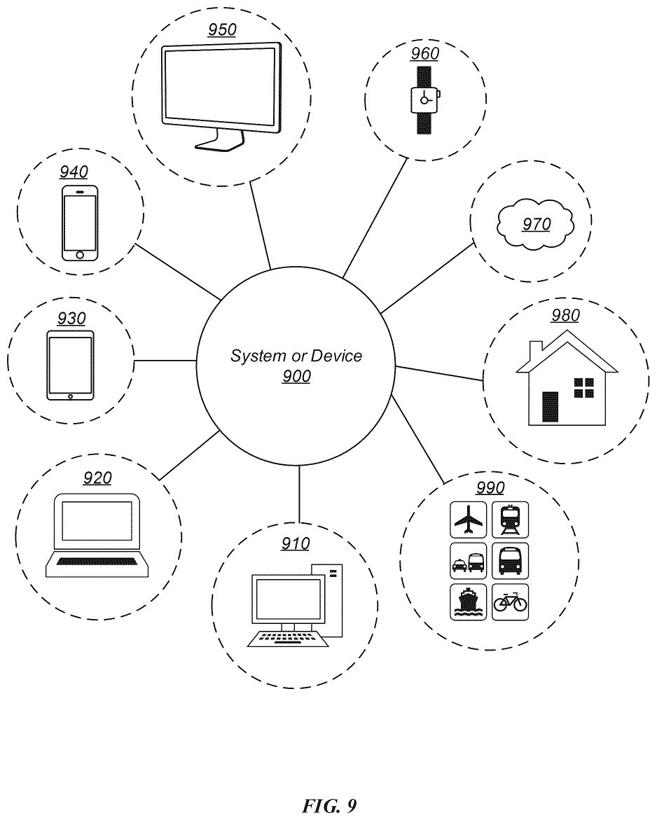

Turning now to FIG. 9, various types of systems that may include any of the circuits, devices, or systems discussed above are illustrated. System or device 900, which may incorporate or otherwise utilize one or more of the techniques described herein, may be utilized in a wide range of areas. For example, system or device 900 may be utilized as part of the hardware of systems such as a desktop computer 910, laptop computer 920, tablet computer 930, cellular or mobile phone 940, or television 950 (or set-top box coupled to a television).

Similarly, disclosed elements may be utilized in a wearable device 960, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 900 may also be used in various other contexts. For example, system or device 900 may be utilized in the context of a server computer system, such as a dedicated server or on shared hardware that implements a cloud-based service 970. Still further, system or device 900 may be implemented in a wide range of specialized everyday devices, including devices 980 commonly found in the home such as refrigerators, thermostats, security cameras, etc. The interconnection of such devices is often referred to as the “Internet of Things” (IoT). Elements may also be implemented in various modes of transportation. For example, system or device 900 could be employed in the control systems, guidance systems, entertainment systems, etc. of various types of vehicles 990.

The applications illustrated in FIG. 9 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as design simulation, design synthesis, circuit fabrication, etc.

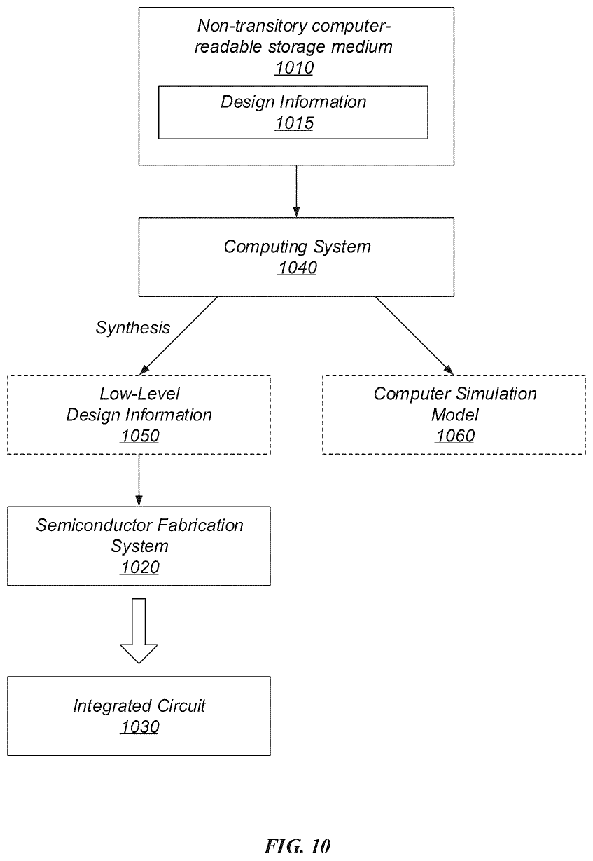

FIG. 10 is a block diagram illustrating an example of a non-transitory computer-readable storage medium that stores design information 1015, according to some embodiments. In the illustrated embodiment, computing system 1040 is configured to process design information 1015. This may include executing instructions included in design information 1015, interpreting instructions included in design information 1015, compiling, transforming, or otherwise updating design information 1015, etc. Therefore, design information 1015 controls computing system 1040 (e.g., by programming computing system 1040) to perform various operations discussed below, in some embodiments.

In the illustrated example, computing system 1040 processes design information 1015 to generate both computer simulation model of hardware circuit 1060 and low-level design information 1050. In other embodiments, computing system 1040 may generate only one of these outputs, may generate other outputs based on design information 1015, or both. Regarding computer simulation model of hardware circuit 1060, computing system 1040 may execute instructions of a hardware description language that includes register transfer level (RTL) code, behavioral code, structural code, or some combination thereof. The simulation model may perform the functionality specified by design information 1015, facilitate verification of the functional correctness of the hardware design, generate power consumption estimates, generate timing estimates, etc.

In the illustrated example, computing system 1040 also processes design information 1015 to generate low-level design information 1050 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on low-level design information 1050 (potentially among other inputs), semiconductor fabrication system 1020 is configured to fabricate integrated circuit 1030 (which may correspond to functionality of the computer simulation model of hardware circuit 1060). Note that computing system 1040 may generate different simulation models based on design information at various levels of description, including low-level design information 1050, design information 1015, and so on. The data representing low-level design information 1050 and computer simulation model of hardware circuit 1060 may be stored on non-transitory computer-readable storage medium 1010, or on one or more other media.

In some embodiments, low-level design information 1050 controls (e.g., programs) semiconductor fabrication system 1020 to fabricate integrated circuit 1030. Thus, when processed by the fabrication system, the design information may program the fabrication system to fabricate a circuit that includes various circuitry disclosed herein.

Non-transitory computer-readable storage medium 1010 may comprise any of various appropriate types of memory devices or storage devices. Non-transitory computer-readable storage medium 1010 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash memory, magnetic media, e.g., a hard drive, or optical storage; registers, or other similar types of memory elements, etc. Non-transitory computer-readable storage medium 1010 may include other types of non-transitory memory as well, or combinations thereof. Accordingly, non-transitory computer-readable storage medium 1010 may include two or more memory media, which may reside in different locations—for example, in different computer systems that are connected over a network.

Design information 1015 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 1040, semiconductor fabrication system 1020, or both. In some embodiments, design information 1015 may also include one or more cell libraries that specify the synthesis, layout, or both of integrated circuit 1030. In some embodiments, design information 1015 is specified in whole, or in part, in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1030 may, in various embodiments, include one or more custom macrocells, such as memories, analog or mixed-signal circuits, and the like. In such cases, design information 1015 may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1020 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1020 may also be configured to perform various testing of fabricated circuits for correct operation.

In various embodiments, integrated circuit 1030 and computer simulation model of hardware circuit 1060 are configured to operate according to a circuit design specified by design information 1015, which may include performing any of the functionality described herein. For example, integrated circuit 1030 may include any of various elements shown in FIGS. 1-6. Further, integrated circuit 1030 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model does not imply that the instructions must be executed in order for the element to be met, but rather, specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by design information 1015. The different circuit implementations may affect the performance, area, power consumption, etc. of a given design (potentially with tradeoffs between different design goals), but the logical function does not vary among the different circuit implementations of the same circuit design.

In some embodiments, the instructions included in design information 1015 provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information included in low-level design information 1050. Low-level design information 1050 may program semiconductor fabrication system 1020 to fabricate integrated circuit 1030.

The present disclosure includes references to an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third,” when applied to a feature, do not imply any type of ordering (e.g., spatial, temporal, logical, etc.), unless stated otherwise.

The phrase “based on” is used to describe one or more factors that affect a determination.

This term does not foreclose the possibility that additional factors may affect the determination. That is, a determination may be solely based on specified factors, or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, a circuit, or a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), a functional unit, a memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as a structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits, or portions thereof, may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a first integrated circuit including a first memory control circuit configured to generate a first memory access command; and
a second integrated circuit coupled to the first integrated circuit via a plurality of bit lines, wherein the second integrated circuit includes:
a memory array circuit including a plurality of memory cells; and
a second memory control circuit configured, in response to receiving the first memory access command, to select a subset of the plurality of memory cells;
wherein the subset of the plurality of memory cells is configured to generate a respective plurality of signals on the plurality of bits lines; and
wherein the first memory control circuit is further configured to receive the respective plurality of signals via the plurality of bit lines.

2. The apparatus of claim 1, wherein the first memory control circuit is further configured to amplify the respective plurality of signals to determine data stored in the subset of the plurality of memory cells.

3. The apparatus of claim 1, wherein, the first memory control circuit is further configured, in response to a determination that a particular time period has elapsed since generating the first memory access command, to amplify the respective plurality of signals.

4. The apparatus of claim 1, wherein the second memory control circuit is further configured to transmit a ready signal to the first integrated circuit in response to a determination that a particular period of time has elapsed since receiving the first memory access command; and
wherein the first memory control circuit is further configured, in response to receiving the ready signal, to amplify the respective plurality of signals.

5. The apparatus of claim 1, wherein the second memory control circuit is further configured to pre-charge the plurality of bit lines in response to a determination that the first memory control circuit has sensed data stored in the subset of the plurality of memory cells.

6. The apparatus of claim 1, wherein the plurality of memory cells includes a plurality of static random-access memory cells.

7. A method, comprising:
receiving, by a particular memory control circuit on a particular integrated circuit of a plurality of integrated circuits, a memory access command from a different memory control circuit on a different integrated circuit of the plurality of integrated circuits;
activating, by the particular memory control circuit using the memory access command, a subset of a plurality of memory cells included on the particular integrated circuit;
generating, by the subset of the plurality of memory cells, respective signals of a plurality of signals on corresponding bit lines of a plurality of bit lines, wherein the plurality of bit lines are coupled between the particular integrated circuit and the different integrated circuit;
receiving, by the different memory control circuit, the respective plurality of signals; and
determining, by the different memory control circuit using the respective plurality of signals, data stored in the subset of the plurality of memory cells.

8. The method of claim 7, wherein determining, by the different memory control circuit, the data stored in the subset of the plurality of memory cells includes amplifying, by the different memory control circuit, the plurality of signals.

9. The method of claim 8, further comprising amplifying, by the different memory control circuit, the plurality of signals in response to determining a particular time period has elapsed since sending the memory access command to the particular memory control circuit.

10. The method of claim 8, further comprising:
transmitting, by the particular memory control circuit, a ready signal in response to determining a particular time period has elapsed since receiving the memory access command; and
amplifying, by the different memory control circuit, the plurality of signals in response to receiving the ready signal.

11. The method of claim 7, further comprising pre-charging, by the particular memory control circuit, the plurality of bit lines in response to determining the different memory control circuit has determined the data stored in the subset of the plurality of memory cells.

12. The method of claim 7, wherein the plurality of memory cells is arranged in an array including a plurality of rows and a plurality of columns, wherein the subset of the plurality of memory cells are coupled to a particular word line of a plurality of word lines, and wherein the subset of the plurality of memory cells are coupled to corresponding column bit lines of a plurality of column bit lines, and wherein activating, by the particular memory control circuit, the subset of the plurality of memory cells includes coupling, by the particular memory control circuit, the corresponding column bit lines of the plurality of column bit lines to corresponding bit lines of the plurality of bit lines.

13. The method of claim 12, further comprising:
performing, by the particular memory control circuit, a decode operation using an address included in the memory access command; and
activating, by the particular memory control circuit, the particular word line using a result of the decode operation.

14. An apparatus, comprising:
a memory array including a plurality of memory cells; and
a memory control circuit configured to:
receive a first memory access command via a communication bus; and
select a first subset of the plurality of memory cells using the first memory access command; and
wherein the first subset of the plurality of memory cells is configured to generate a plurality of signals on corresponding ones of a plurality of bit lines that are coupled to external access point on an integrated circuit that includes the memory array and the memory control circuit.

15. The apparatus of claim 14, wherein the memory control circuit is further configured to pre-charge the plurality of bit lines in response to a determination that a particular period of time has elapsed since selecting the first subset of the plurality of memory cells.

16. The apparatus of claim 14, wherein the memory control circuit is further configured to transmit a ready signal via the communication bus in response to a determination that a particular period of time has elapsed since selecting the first subset of the plurality of memory cells.

17. The apparatus of claim 14, further comprising a circuit block configured to generate a second memory access command, and wherein the memory control circuit is further configured to:
receive the second memory access command; and
select a second subset of the plurality of memory cells using the second memory access command.

18. The apparatus of claim 14, wherein the plurality of memory cells are disposed in a plurality of columns that include corresponding subsets of the plurality of memory cells coupled to corresponding ones of the plurality of bit lines.

19. The apparatus of claim 18, wherein to select the first subset of the plurality of memory cells, the memory control circuit is further configured to activate a given word line of a plurality of word lines, wherein the given word line is coupled to corresponding memory cells in the plurality of columns.

20. The apparatus of claim 19, wherein the first memory access command includes an address, and wherein to activate the given word line, the memory control circuit is further configured to decode the address.
